(19) United States
(12) Patent Application Publication
(10) Pub. No.: US 2026/0101539 A1
(43) Pub. Date: Apr. 9, 2026

(54) GROUP III-N DEVICE WITH INTERSPERSED GATE STRUCTURE

(71) Applicant: TEXAS INSTRUMENTS INCORPORATED, Dallas, TX (US)

(72) Inventors: Yoganand Saripalli, Allen, TX (US); James Teherani, Plano, TX (US)

(21) Appl. No.: 18/907,986

(22) Filed: Oct. 7, 2024

(51) Int. Cl. H01L 29/47; H01L 21/285; H01L 29/20; H01L 29/66; H01L 29/778

(52) U.S. Cl. CPC H10D 30/675; H10D 30/015; H10D 30/475; H10D 30/6738; H10D 62/85; H10D 62/8503; H10D 64/0124; H10D 64/64

(57) ABSTRACT

Semiconductor devices including an interspersed gate structure are described. In one example, a semiconductor device comprises a semiconductor substrate including a source region, a gate region, a drain region, and a drain access region, where a heterojunction structure is disposed over the semiconductor substrate. The heterojunction structure includes a buffer layer over the semiconductor substrate and a barrier layer over the buffer layer. A p-doped III-N layer is disposed over the barrier layer in the gate region, where the p-doped III-N layer may contain a concentration profile of an element with one or more peaks at different distances from a surface of the p-doped III-N layer.

### FIELD OF THE DISCLOSURE

Disclosed implementations relate generally to the field of group III-N semiconductor devices and their fabrication.

### BACKGROUND

Group III nitride materials (also referred to as III-N materials) possess a unique combination of physical and electrical properties found to be beneficial in modern microelectronics and optoelectronics. Among these properties are wide bandgap, high saturated drift velocity and breakdown voltage, high thermal conductivity, robust chemical and thermal stability, etc. Due to these characteristics, III-N materials are being considered as promising materials for fabrication of powerful high-frequency transistors capable of functioning at high temperatures and in hostile environments. Whereas advances in III-N devices and their fabrication continue to grow apace, several lacunae remain, thereby requiring further innovation as will be set forth hereinbelow.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a semiconductor device comprises a semiconductor substrate including a source region, a gate region, a drain region, and a drain access region, where a heterojunction structure is disposed over the semiconductor substrate. The heterojunction structure includes a buffer layer over the semiconductor substrate and a barrier layer over the buffer layer. A p-doped III-N layer is disposed over the barrier layer in the gate region, where the p-doped III-N layer may contain a concentration profile of an element with one or more peaks at different distances from a surface of the p-doped III-N layer.

In one example, a semiconductor device comprises a semiconductor substrate including a source region, a gate region, a drain region, and a drain access region, where a heterojunction structure is disposed over the semiconductor substrate. The heterojunction structure includes a buffer layer over the semiconductor substrate and a barrier layer over the buffer layer. A p-doped III-N layer is disposed over the barrier layer in the gate region, where the p-doped III-N layer may include one or more Al_{X}Ga_{(1-X)}N layers.

In one example, a method of fabricating a III-N semiconductor device is disclosed. The method comprises, among others, forming a heterojunction structure over a semiconductor substrate including a source region, a gate region, a drain region, and a drain access region between the gate region and the drain region, where the heterojunction structure includes a buffer layer over the semiconductor substrate and a barrier layer over the buffer layer; and forming a p-doped III-N layer over the barrier layer in the gate region, the p-doped III-N layer containing a concentration profile of an element with one or more peaks at different distances from a surface of the p-doped III-N layer. In some arrangements, the p-doped III-N layer may be grown using an epitaxial process with pulsed doping of the element, where the element may comprise aluminum, boron, thallium or indium. In some arrangements. the one or more peaks of an elemental concentration profile may be interspersed within the p-doped III-N layer, where the p-doped III-N layer includes magnesium (Mg) with a suitable concentration. In some arrangements, the one or more peaks of an elemental concentration profile may be spaced apart by a distance ranging from about 1 nm to about 20 nm.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure are described in the following Detailed Description taken in connection with the appended claims and with reference to the attached drawing Figures in which:

FIGS. 1A-1M depict cross-sectional views of a semiconductor device including a GaN device at various stages of a process flow according to an example of the present disclosure;

FIGS. 2A and 2B depict a bandgap diagram and hole concentration profile, respectively, corresponding to an example interspersed gate structure of the present disclosure; and

FIG. 3 is a flowchart of a method of fabricating a III-N semiconductor device according to some examples.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of improving performance characteristics of semiconductor devices based on Group III nitride materials such as gallium nitride (GaN) devices.

GaN devices, e.g., GaN transistors, provide certain performance advantages over silicon, including lower on-state resistance (e.g., drain-source resistance or R_{DSON}), lower switching losses, and improved breakdown voltage, among others. GaN transistors include a hetero epitaxy structure with a junction between materials of different bandgaps (e.g., a heterojunction structure), such as aluminum gallium nitride (AlGaN) and gallium nitride, to provide a 2-dimensional electron gas (2DEG) formed within the AlGaN/GaN hetero epitaxy structure that is used for device operation—e.g., forming a channel of the GaN device. The 2-dimensional electron gas (2DEG) may be referred to as a 2DEG channel. Depletion mode (DMODE) GaN transistors are normally on, whereas enhancement mode (EMODE) GaN transistors are normally off. In some examples, EMODE GaN transistors include a gate stack with a p-type doped gallium nitride (p-GaN) layer that depletes the 2DEG beneath the gate stack at zero or negative gate bias. In some examples, the p-GaN layer may comprise a GaN layer doped with magnesium (Mg) or other p-type dopants. Applying a positive gate voltage, e.g., a threshold voltage, enhances the 2DEG under the gate and turns the EMODE GaN device on to allow current flow between the source and the drain.

In some examples, a GaN device may be formed with one or more GaN layers over a suitable semiconductor substrate, e.g., including a silicon substrate, where a portion of the GaN layers may form a heterojunction structure over the semiconductor substrate, with a p-GaN layer overlying the heterojunction structure for effectuating EMODE device functionality. The p-GaN layer may be doped with appropriate levels of p-type dopants to control the threshold voltage (V_{T} or V_{TH}) of the GaN device. In general, higher threshold voltages are desired in order to reduce the likelihood of accidentally turning on an EMODE device, increase operational margins, reduce leakage current (e.g., off-state I_{DS}), etc.

Whereas a p-type dopant such as magnesium is commonly used as an acceptor species in the fabrication of EMODE gate stack structures, magnesium has a low ionization efficiency that may result in insufficient hole concentrations for maintaining desired threshold voltages. Accordingly, high concentrations of the dopant (e.g., magnesium) may be used in some implementations to achieve acceptable threshold voltages. However, high concentrations of the dopants in an EMODE gate stack structure may cause diffusion into the active layers of a device (e.g., heterojunction structure, 2DEG channel), resulting in deteriorated performance such as increased on-resistance (R_{DSON}), post-bias V_{TH} shift, etc.

Examples of the present disclosure recognize the foregoing challenges and provide solutions for improving acceptor ionization efficiency (thus increasing hole concentration) in the gate stacks of EMODE devices to achieve acceptable threshold voltages for given dopant concentrations (e.g., given chemical concentrations). In some arrangements, an interspersed gate stack structure is provided where one or more elements (e.g., aluminum) may be interspersed within a p-GaN layer of the gate stack. Locally incorporating such elements within the p-GaN layer locally increases the bandgap energy of the p-GaN layer (e.g., proportional to locally varying concentration of the elements) such that acceptor ionization efficiency within the p-GaN layer may improve overall. Depending on implementation, incorporating such elements may result in a wide bandgap material (e.g., a material having a greater bandgap energy than GaN of the p-GaN layer), such as Al_{X}Ga_{(1-X)}N, where the fractional value of X may be varied between 0 and 1 (e.g., 0<X≤1). In some examples, one or more layers (or sublayers) of a wide bandgap energy may be formed in the gate stack structure at various depths. In this manner, the ionization efficiency of the p-type dopant (e.g., Mg) may be boosted throughout the p-GaN layer—e.g., across a vertical dimension of the p-GaN layer, across the thickness of the p-GaN layer.

As described in more detail herein, a gate stack may be configured with customizable bandgap energy profile(s) across a thickness of a p-GaN layer in the gate stack—e.g., having locally varying concentrations of the element(s) selected for increasing bandgap energy of the p-GaN layer. In this manner, ionization efficiency of p-type dopants (hence hole concentration) can be increased such that desirable threshold voltages may be obtained with p-type dopant concentrations determined to mitigate the risk of dopant diffusion, which may be difficult to obtain otherwise. Whereas the examples herein may provide various structures, materials and processes that may engender these and other beneficial effects, no particular result is a requirement unless explicitly recited in a particular claim.

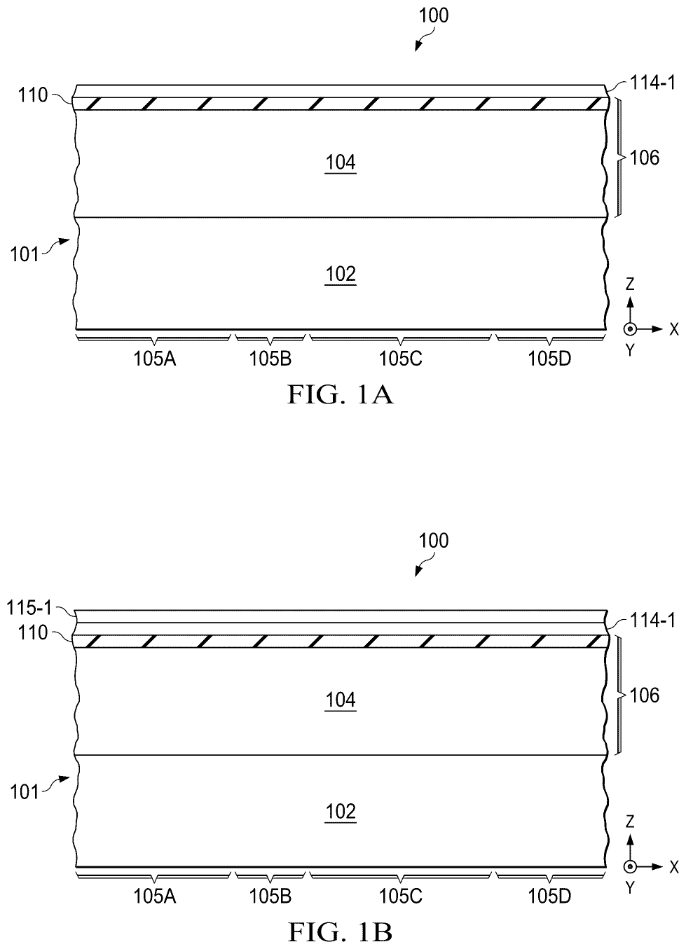

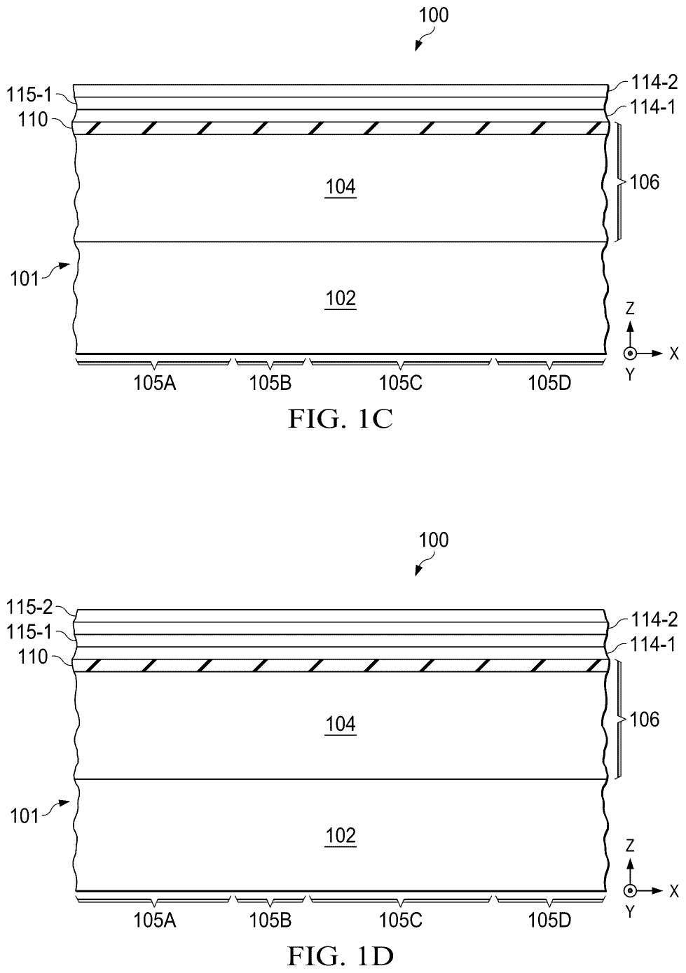

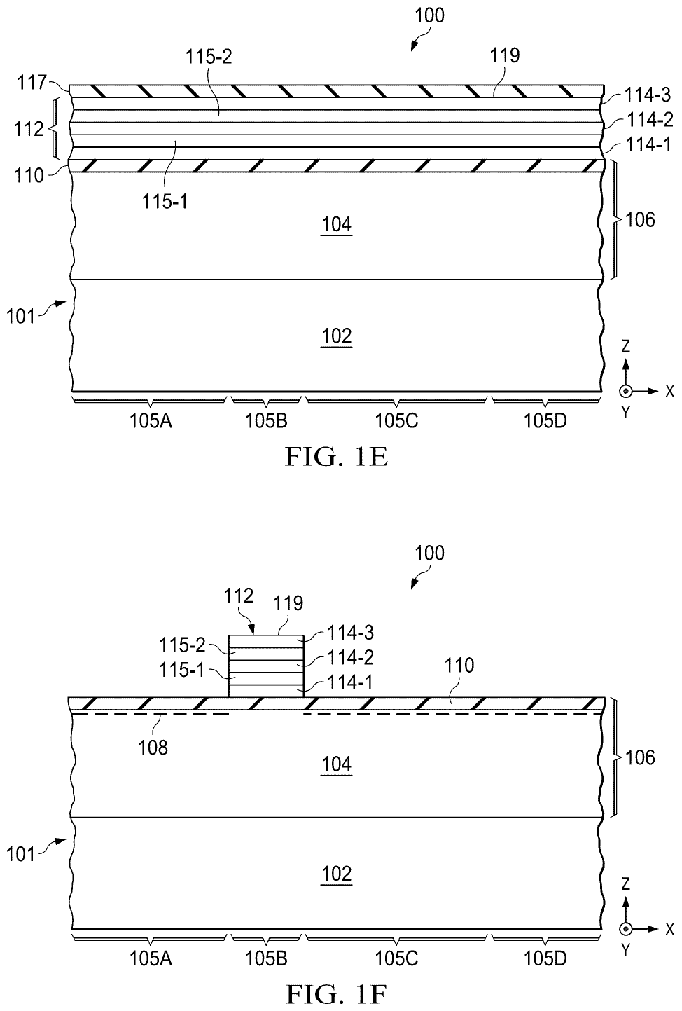

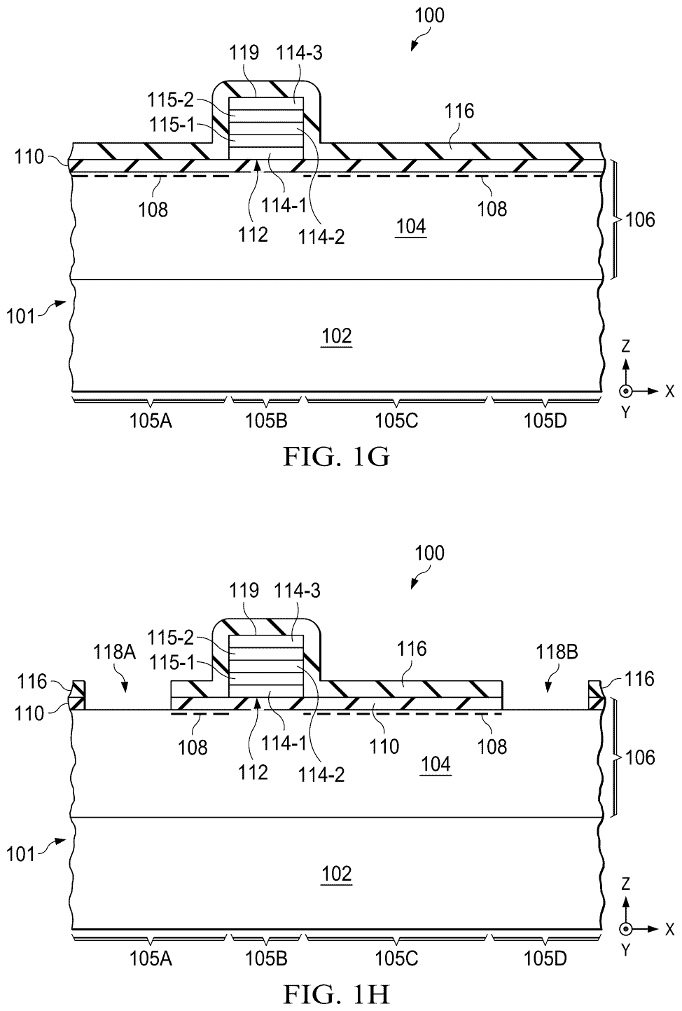

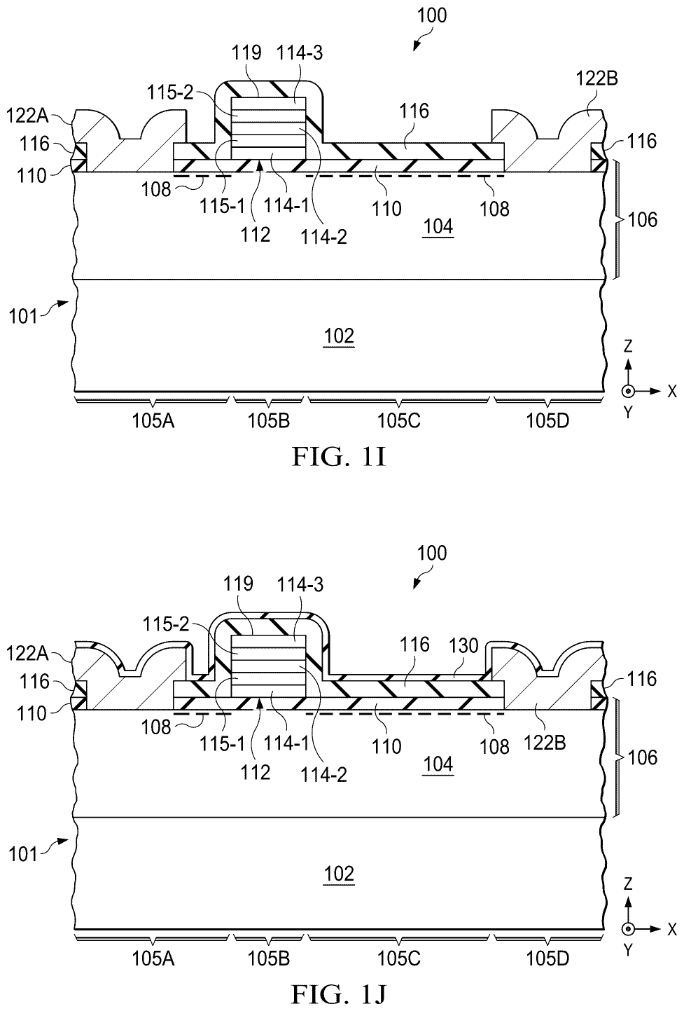

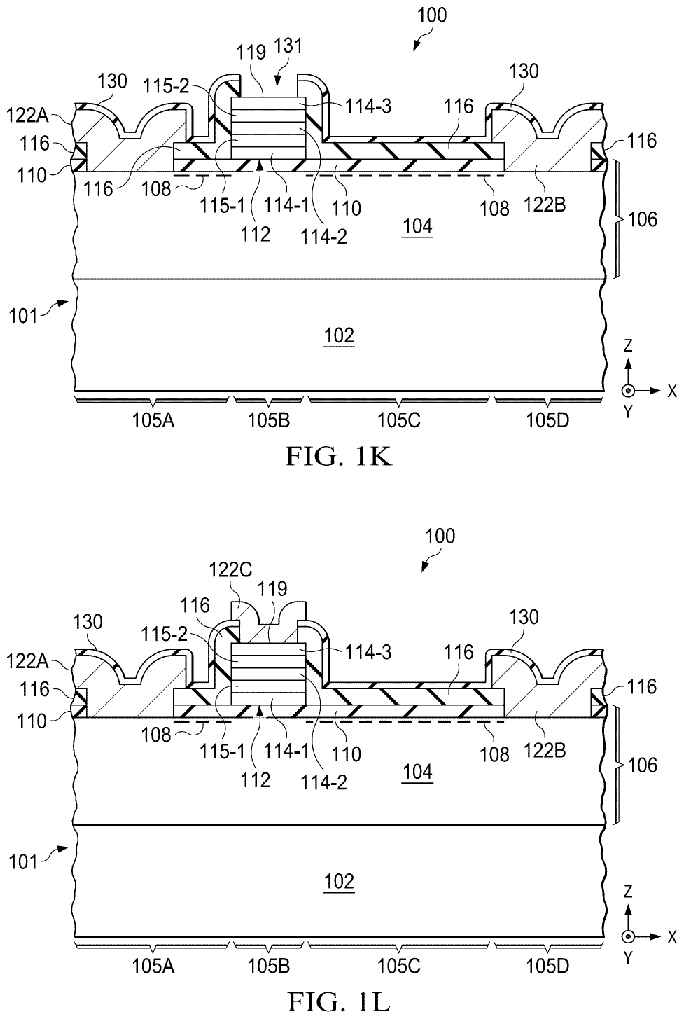

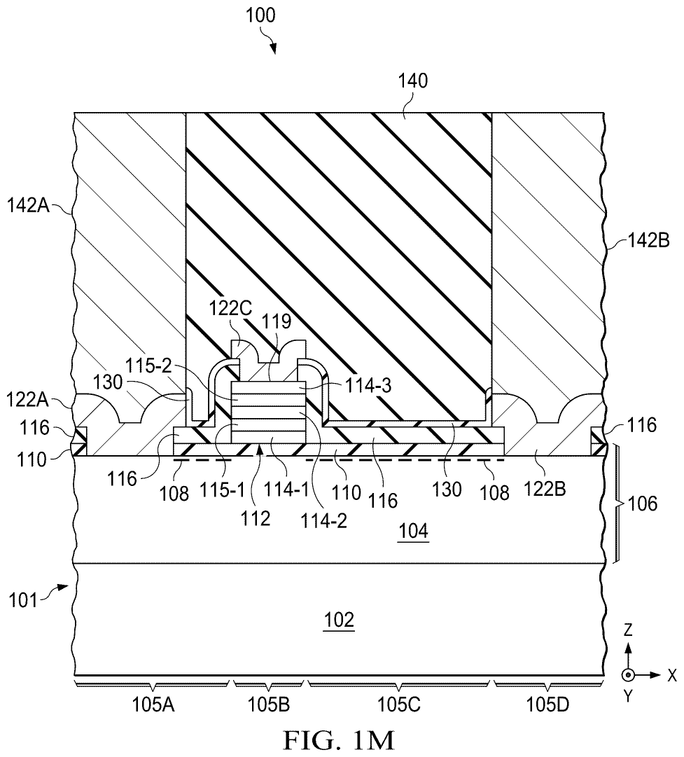

Referring to the drawings, FIGS. 1A-1M depict cross-sectional views of a semiconductor device 100 including a GaN device 101 at various stages of a process flow. The GaN device 101 includes a gate structure having a p-doped III-N layer (e.g., p-GaN layer). In some examples, the p-doped III-N layer has a concentration profile of an element with one or more peaks at different distances from a surface of the p-doped III-N layer. Such an element (e.g., aluminum), when incorporated in the III-N layer, increases bandgap energy of the III-N layer. In some examples, the p-doped III-N layer includes one or more Al_{X}Ga_{(1-X)}N layers having a relatively greater bandgap energy when compared with the GaN layer. In other words, the p-doped III-N layer of the gate stack structure of the GaN device 101 includes one or more increased bandgap regions (which may also be referred to as bandgap-boosted regions) interspersed within the p-doped III-N layer.

FIG. 1A depicts an intermediate stage of the semiconductor device 100 formed on a portion of a semiconductor substrate 102, which may be provided as a silicon wafer, a silicon-on-sapphire wafer, or a silicon carbide wafer, and/or as semiconductor substrates including cores configured for matching coefficient of thermal expansion (CTE), and/or the like. A buffer layer 104 comprising one or more layers of III-N semiconductor material is formed on the substrate 102. In some examples where the substrate 102 is implemented as a silicon wafer or a sapphire wafer, the buffer layer 104 may include a nucleation layer having a stoichiometry that includes aluminum to match a lattice constant of the substrate 102. In some examples, the buffer layer 104 may further include layers/sublayers of aluminum gallium nitride (AlGaN) with decreasing aluminum content, including an unintentionally doped (UID) GaN sublayer in some arrangements. For purposes of the examples herein, the various layers/sublayers of a buffer layer, e.g., the buffer layer 104, are not specifically shown in the Figures of the present disclosure.

Depending on implementation, the buffer layer 104 may have a thickness of about 1 micron (μm) to several microns, e.g., 3.5 μm to 7.0 μm, which may be formed by a suitable epitaxial process, e.g., a metal organic vapor phase epitaxy (MOVPE) process (also known as organometallic vapor phase epitaxy (OMVPE) or metalorganic chemical vapor deposition (MOCVD)), where several sequential steps may be performed to form the various constituent layers and/or sublayers. In some arrangements, an example buffer layer 104 may therefore comprise a stack of multiple layers/sublayers of suitable materials and compositions (e.g., GaN, AlGaN, etc.) as noted above, where the layers/sublayers may have variable thicknesses depending on the technology and device application. In some arrangements, the buffer layer 104 may include AlGaN-based transition layers, epitaxial layers with strain-layer superlattice (SLS) structures, and the like.

The buffer layer 104 may be formed over an area of the substrate 102, where different regions such as a source region 105A, a gate region 105B, a drain region 105D and a drain access region 105C between the gate region 105B and the drain region 105D may be provided with respect to the GaN device 101. The source region 105A may be regarded as including a source access region (not specifically shown in the Figures), which may refer to a region between a source electrode (e.g., source electrode 122A shown in FIGS. 1I-1M) and the gate region 105B similar to the drain access region 105C. A channel layer may be provided as part of the buffer layer 104—e.g., a top portion of the buffer layer 104 proximate to a barrier layer 110. Whereas a channel layer may primarily include GaN material, there may be optional trace amounts of other group III elements, such as aluminum or indium, in some implementations.

A barrier layer 110 comprising III-N semiconductor material is formed over the buffer layer 104 in a suitable epitaxy process. In an example arrangement, the barrier layer 110 may have a thickness ranging from about 1 nanometer (nm) to about 60 nm, and may include aluminum and nitrogen. In some versions of this example, the barrier layer 110 may include gallium at a lower atomic percent than aluminum. In some versions, the barrier layer 110 may also include indium. In some examples, the barrier layer 110 includes an AlGaN layer.

The barrier layer 110 over buffer layer 104 is operable as part of a heterojunction structure 106 for causing the formation of a 2DEG (e.g., 2DEG 108 shown in FIGS. 1F-1M)) proximate to an interface between the barrier layer 110 and the buffer layer 104. In some examples, the stoichiometry and thickness of the barrier layer 110 may be configured to provide a suitable free charge carrier density (e.g., 3×10¹² cm⁻² to 2×10¹³ cm⁻²) of the 2DEG for facilitating the device operation.

For purposes of effectuating EMODE functionality with increased acceptor ionization efficiency, an interspersed p-doped III-N layer may be formed over the barrier layer 110. In the context of the present disclosure, an interspersed p-doped III-N layer may be a p-doped III-N layer that includes at least one layer or sublayer comprising a wide bandgap semiconductor material operable as an increased bandgap region (or bandgap-boosted region) within the p-doped III-N layer. In some examples, an interspersed p-doped III-N layer may also be referred to as an interleaved or stacked p-III-N or p-GaN layer. In some examples, the interspersed p-doped III-N layer has a concentration profile of an element with one or more peaks at different distances from a surface of the interspersed p-doped III-N layer. Such an element (e.g., aluminum), when incorporated in the III-N layer, increases bandgap energy of the III-N layer. As will be set forth below, such elements or one or more (sub)layers including such elements may be interspersed in a p-doped III-N layer by using a pulsed epitaxy process that includes a sequence of growth steps selectively modulated to incorporate a Group III element, e.g., aluminum, boron, thallium or indium, at different distances or depths from a surface (e.g., a top surface) of a completed p-III-N layer. Although various combinations of Group III elements (e.g., aluminum, boron, thallium or indium) may be used for forming the (sub)layers operable as increased bandgap regions (bandgap-boosted regions) in a p-GaN layer, representative examples including Al_{X}Ga_{(1-X)}N layers are described below without limitation.

By way of illustration, FIGS. 1A-1E depict a plurality of stages with respect to forming an interspersed p-GaN layer using a pulsed epitaxy process according to some examples. In some arrangements, a pulsed MOCVD process may be implemented where suitable precursors of aluminum, e.g., trimethylaluminum (TMA), may be selectively supplied in a pressurized reaction chamber for configurable time periods in addition to GaN precursors such as ammonia (NH₃), trimethylgallium (TMG) or triethylgallium (TEG). The precursors may be transported using a carrier gas (e.g., N₂, H_{2,} etc.) in a coordinated timing sequence in order to form Al_{X}Ga_{(1-X)}N layers at select depths or distances during the growth process. Accordingly, a stack structure of an interspersed p-GaN layer having a suitable overall thickness may be obtained after completing the growth process. In some additional and/or alternative arrangements, a pulsed molecular beam epitaxy (MBE) process may be implemented for selectively interleaving Al_{X}Ga_{(1-X)}N layers in a p-GaN layer in similar fashion, where a direct metal source, e.g., aluminum cell, may be used as a precursor in a heated reaction chamber having ultrahigh vacuum conditions.

Depending on the number and spatial configuration of increased bandgap regions to be implemented in a GaN device, e.g., GaN device 101, a pulsed epitaxy process (e.g., pulsed MOCVD or pulsed MBE) may be modulated—e.g., to alternate between growing p-doped GaN (sub)layers and growing Al_{X}Ga_{(1-X)}N (sub)layers in various permutations and combinations, to incorporate one or more elements (e.g., aluminum) that increase bandgap energy of the GaN layer. Growth phases of p-doped GaN (sub)layers and Al_{X}Ga_{(1-X)}N (sub)layers (or growth phases incorporating the one or more elements) may be repeated until a desired overall thickness of a completed p-GaN layer including a designated number of increased bandgap regions is achieved. For purposes of examples herein, the terms “layer” and “layers” may include and/or may be interchangeably used with terms “sublayer” and “sublayers” depending on the context unless otherwise stated.

In some examples, an interspersed p-GaN layer containing one or more increased bandgap regions may be fabricated where an overall Mg concentration of about 1×10¹⁷ atoms/cm³ to 1×10²¹ atoms/cm³ may be provided as a p-type dopant. In some examples, an interspersed p-GaN layer may have an overall thickness of about 20 nm to 200 nm. In some examples, individual p-doped GaN sublayers may have a thickness of about 10 nm to 20 nm. In some examples, individual Al_{X}Ga_{(1-X)}N sublayers (or individual regions including aluminum) may have a thickness of about 1 nm to 15 nm. In some arrangements, the thickness of Al_{X}Ga_{(1-X)}N sublayers may be dependent on the fractional Al content, e.g., sublayers with less Al content may have greater thicknesses and vice versa. As an illustration, an increased bandgap region with a fractional Al content of 0.9 (corresponding to 90% Al and 10% Ga) to 1.0 (corresponding to 100% Al and no Ga, e.g., aluminum nitride or AlN) may have a thickness as low as 0.5 nm whereas an increased bandgap region with a fractional Al content of 0.05 may have a thickness greater than 20 nm.

In some arrangements, an interspersed p-GaN layer may be fabricated as a sandwich structure where a bottom p-GaN layer overlying the barrier layer 110 and a top p-GaN layer may “bookend” a core of alternating p-GaN and increased bandgap regions (e.g., Al_{X}Ga_{(1-X)}N layers). In additional and/or alternative arrangements, one or more p-GaN layers and one or more increased bandgap regions (e.g., Al_{X}Ga_{(1-X)}N layers) may be provided in any order or sequence to operate as an interspersed p-GaN layer.

As illustrated in FIG. 1A, a p-GaN sublayer 114-1 is formed over the barrier layer 110, e.g., in a pulsed epitaxy stage as set forth above. In FIG. 1B, a first increased bandgap region (e.g., Al_{X}Ga_{(1-X)}N sublayer) 115-1 is formed over the p-GaN sublayer 114-1, e.g., in a pulsed epitaxy stage as set forth above, where Al content may be varied depending on implementation. As previously noted, a higher Al content may allow the fabrication of a thinner Al_{X}Ga_{(1-X)}N sublayer. Further, higher Al content may increase Mg ionization efficiency according to examples herein.

FIG. 1C depicts a stage where a p-GaN sublayer 114-2 is formed over the first increased bandgap region 115-1. FIG. 1D depicts a stage where a second increased bandgap region (e.g., Al_{X}Ga_{(1-X)}N sublayer) 115-2 is formed over the p-GaN sublayer 114-2, where the second increased bandgap region 115-2 may have a same or different Al content and/or thickness as the first increased bandgap region 115-1. As noted previously, the formation of p-GaN sublayers and increased bandgap regions (e.g., Al_{X}Ga_{(1-X)}N sublayers) may continue repetitively in a pulsed epitaxy process in various sequences until an interspersed p-GaN layer 112 (shown in FIG. 1E) having a desired overall thickness is obtained. In some additional and/or alterative arrangements, additional layers such as an AlGaN cap layer of about 4 nm to 10 nm (e.g., devoid of p-doping) and/or a low-pressure chemical vapor deposition (LPCVD) silicon nitride (SiN) cap layer of about 10 nm to 20 nm, which are collectively shown as a cap layer 117, may be optionally provided over the interspersed p-GaN layer 112 as illustrated in FIG. 1E.

Depending on implementation, p-GaN sublayers of an interspersed p-GaN layer may have same or different thicknesses in some versions of the examples herein. Likewise, increased bandgap regions (e.g., Al_{X}Ga_{(1-X)}N sublayers) may have same or different thicknesses and/or Al fractions in some versions of the examples.

As multiple increased bandgap regions (e.g., Al_{X}Ga_{(1-X)}N sublayers) 115-1, 115-2 are sequentially formed using pulsed epitaxy stages, an aluminum concentration profile may be developed in the interspersed p-GaN layer 112. In some arrangements, one or more peaks of an aluminum concentration profile (indicating maximum aluminum concentrations) may be present at different distances from a reference surface, e.g., surface 119 of the interspersed p-GaN layer 112, generally corresponding to a midpoint location of respective increased bandgap regions 115-1, 115-2. The presence of aluminum peaks at different distances is representative of increased bandgap regions in the interspersed p-GaN layer 112, where Mg ionization efficiency is increased. In some arrangements, the increased bandgap regions may be configured to have the greater bandgap occurring at regular and/or irregular intervals, e.g., corresponding to the presence of the aluminum peaks, where the greater bandgap energy increases p-type dopant ionization efficiency resulting in increased hole concentration.

FIG. 1F depicts a stage after patterning the interspersed p-GaN layer 112 using a mask and appropriate photolithography and etch process to form a part of a gate stack, which may include optional capping layers in some implementations (e.g., AlGaN/SiN cap layers 117 described with reference to FIG. 1E, not shown in FIG. 1F) in addition to a gate electrode to be subsequently formed over the patterned interspersed p-GaN layer 112 (and the additional capping layers if present). As a result of patterning the interspersed p-GaN layer 112 (e.g., removing portions of the interspersed p-GaN layer 112 outside the gate region 105B), 2DEG 108 may be established in the channel layer outside the gate region 105B. For purposes of the present disclosure, the interspersed p-GaN layer 112 including increased bandgap portions (e.g., Al_{X}Ga_{(1-X)}N sublayers) 115-1, 115-2 in the gate region 105B may be referred to as an interspersed gate structure without any implied or express limitation.

In some versions of the examples herein, the source region 105A (where a source electrode or contact is to be formed) and the drain region 105D (where a drain electrode or contact is to be formed) may be asymmetrically disposed relative to the gate region 105B although it is not a requirement. For example, there may be a greater lateral distance between the gate region 105B and the drain region 105D than a lateral distance between the gate region 105B and the source region 105A by virtue of an access region, e.g., drain access region 105C, disposed between the gate region 105B and the drain region 105D. In some additional and/or alternative arrangements, a source access region may also be provided between the source region 105A and the gate region 105B in a similar manner, as previously noted, while still having source/drain region asymmetry with respect to the gate region 105B.

Although not specifically shown in FIGS. 1A-1F, a suitable device isolation step may be implemented to achieve isolation with respect to the GaN device 101. Depending on implementation, an isolation step may include mesa etching, implanting, etc., to define a region where the 2DEG 108 outside the active area is absent, eliminated or otherwise disrupted. In some examples, an Ar+ implant at 120 keV having a dosage around 5×10¹⁴ atoms/cm² may be implemented to achieve device isolation.

In some examples, a first dielectric layer 116, e.g., an LPCVD SiN layer, is formed over the barrier layer 110 and the interspersed p-GaN layer 112 including the increased bandgap regions 115-1 and 115-2 in the stage shown in FIG. 1G. In additional and/or alternative arrangements, the first dielectric layer 116 may comprise different materials, e.g., silicon dioxide (SiO₂), silicon oxynitride (SiON), aluminum oxide (Al₂O₃), etc., and may be formed using other techniques such as atomic layer deposition (ALD).

FIG. 1H depicts a stage where source and drain contact apertures 118A, 118B are formed in the source and drain regions 105A, 105B, respectively, using a suitable contact mask and an etch process comprising wet etch and/or dry etch. FIG. 1I depicts a contact metallization stage (including an annealing step in some examples) where a source electrode or contact 122A and a drain electrode or contact 122B are formed in the source and drain regions 105A, 105B, respectively, using appropriate metals such as titanium, nickel, tungsten, platinum, iridium, aluminum, gold, etc., as well as metallic nitrides such as titanium nitride (TiN), tantalum nitride (TaN) and the like. In some implementations, source and drain electrodes 122A, 122B may also include other electrically conductive materials such as carbon nanotubes or graphene.

In some examples, a dielectric layer 130 operable to mask and protect the source and drain electrodes 122A, 122B from subsequent processing, e.g., gate electrode formation, may be provided as set forth in FIG. 1J. Depending on implementation, the dielectric layer 130 may have a thickness of about 10 nm to 30 nm and comprise SiO₂, SiON, SiN, Al₂O₃, etc.

FIG. 1K depicts a stage where a gate electrode photolithography and etch process is performed to form an aperture 131 that exposes the interspersed p-GaN layer stack 112. FIG. 1L depicts a stage where a gate electrode or contact 122C is formed using suitable metallization process similar to the source/drain contact processes set forth above.

FIG. 1M depicts a more completely formed semiconductor device 100 including the GaN device 101, where a source terminal 142A, a gate terminal (not shown in FIG. 1M) and a drain terminal 142B are formed through an insulator 140 comprising, e.g., interlevel dielectric (ILD) and/or pre-metal dielectric (PMD) material, for facilitating electrical contact with source electrode 122A, drain electrode 122B and gate electrode 122C, respectively.

Although the formation of a stacked p-GaN layer including one or more interspersed bandgap-boosted regions has been described above with respect to a process flow where the source and drain electrodes are formed before a gate electrode (e.g., a “gate last” process), it is not a limitation. Accordingly, in some additional and/or alternative examples, a stacked p-GaN layer including interspersed bandgap-boosted regions may be provided in similar manner with respect to a “gate first” process (e.g., where a gate electrode is formed before the formation of source/drain electrodes). Additional details regarding an example gate first process flow may be found in the following U.S. Patent Applications: (i) application Ser. No. 18/756,202, filed on Jun. 27, 2024; and (ii) application Ser. No. 18/788,650, filed on Jul. 30, 2024; each of which is incorporated by reference herein in its entirety for all purposes.

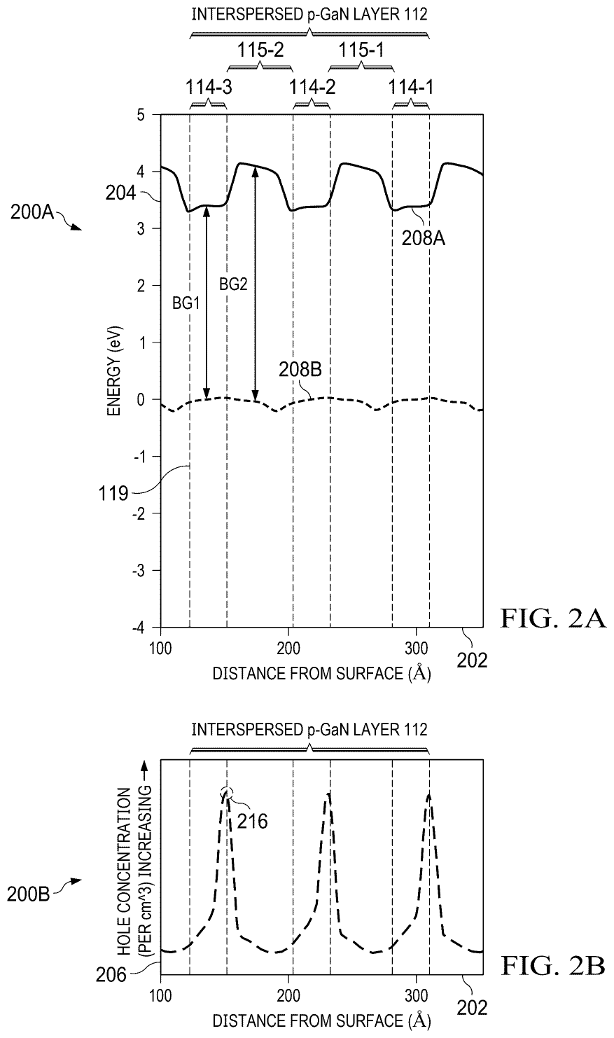

FIGS. 2A and 2B depict an energy band diagram and an associated hole concentration profile, respectively, according to an example interspersed gate structure of the present disclosure. In FIG. 2A, an energy band diagram 200A showing a conduction band edge (E_{C}) 208A and a valence band edge (E_{V}) 208B plotted on Y-axis 204 is depicted as a function of a distance from a reference surface of the interspersed gate structure, e.g., surface 119 of the interspersed p-GaN layer 112 shown in FIG. 1F, plotted on X-axis 202. As described above, the interspersed p-GaN layer 112 includes two (2) increased bandgap regions 115 (e.g., increased bandgap regions 115-1, 115-2), each being sandwiched between the corresponding p-GaN sublayers 114 (e.g., p-GaN sublayers 114-1, 114-2, 114-3).

As shown in the energy band diagram 200A, individual p-GaN sublayers 114 exhibit a first bandgap energy BG1 (e.g., approximately 3.5 eV) whereas individual increased bandgap regions 115 exhibit a second bandgap energy BG2 (e.g., approximately around 4 eV) greater than the first bandgap energy BG1. The greater bandgap energy of the increased bandgap regions 115 may be attributed to one or more elements (e.g., aluminum) incorporated in the p-GaN layer to increase the bandgap energy. In some examples, the second bandgap energy BG2 may vary between approximately 3.5 eV (e.g., bandgap energy of GaN) and approximately 6 eV (e.g., bandgap energy of AlN). Moreover, the increase in the bandgap energy (e.g., bandgap energy offset) stemming from the incorporated elements (e.g., aluminum) may primarily affect (modify) the conduction band edge 208A while the valence band edge 208B remains relatively flat as shown in the energy band diagram 200A. As the bandgap energy is proportional to the concentration of the element incorporated (e.g., aluminum), the overall profile of the conduction band edge 208A may be regarded as a concentration profile of the elements incorporated (e.g., aluminum).

In the depicted example, the conduction band edge 208A exhibits a periodicity corresponding to the presence of regularly spaced bandgap-boosted regions 115, e.g., two (2) bandgap-boosted regions 115-1, 115-2 at corresponding distances from the refenced surface (e.g., the surface 119) are illustrated.

In FIG. 2B, a hole concentration profile 200B is shown as a relationship between a concentration of holes (count per cm³) plotted on Y-axis 206 and the distance from the same reference surface (e.g., surface 119) of the interspersed gate structure plotted on X-axis 202. As illustrated, the hole concentration profile 200B includes a plurality of peaks, e.g., peak 216, corresponding to the increased generation of holes caused by increased ionization efficiency of acceptor species (e.g., magnesium) at least partially due to the locally increased bandgap energy at periodic intervals. As shown in FIGS. 2A and 2B, the peaks of the hole concentration occur at locations (e.g., a vertical locations from the surface 119) where the valence band edge 208B is relatively high (e.g., closer to the conduction band edge 208A). Moreover, polarization charges present at the interfaces between the bandgap-boosted regions 115 and the p-GaN sublayers 114 may cause the peaks of the hole concentration occur near the interfaces.

The hole concentration including one or more peaks may represent increased quantity of holes present in the p-GaN layer of the gate stack (e.g., an integrated quantity of holes throughout the interspersed p-GaN layer 112), which may be attributed to one or more of the bandgap-boosted regions sandwiched between the p-GaN sublayers. The increased quantity of holes is expected to deplete the 2DEG present in the GaN channel layer more efficiently, thus obtaining desired threshold voltages of EMODE GaN devices. Although foregoing examples described with reference to FIGS. 1A-1M, 2A, and 2B include two (2) bandgap-boosted regions (or increased bandgap regions), the present disclosure is not limited thereto. In some examples, EMODE GaN devices may include one (1) bandgap-boosted region. In other examples, EMODE GaN devices may include three (3) bandgap-boosted regions, four (4) bandgap-boosted regions, five (5) bandgap-boosted regions, or even more.

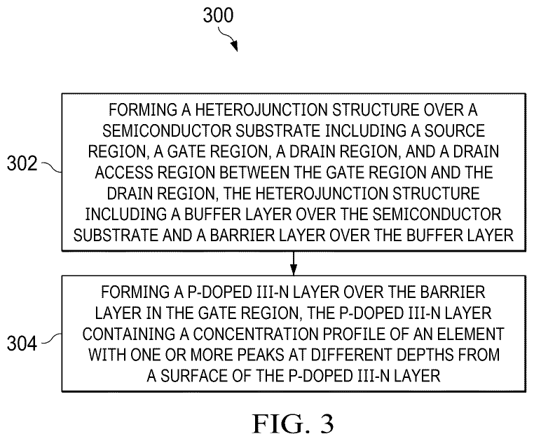

FIG. 3 is a flowchart of a method 300 of fabricating a III-N semiconductor device according to some examples. Method 300 may commence with forming a heterojunction structure over a semiconductor substrate, where the heterojunction structure may include a source region, a gate region, a drain region, and a drain access region between the gate region and the drain region. As previously noted, the heterojunction structure may include a buffer layer over the semiconductor substrate and a barrier layer over the buffer layer. In some examples, these acts set forth at block 302 may relate to aspects of FIG. 1A as described above. At block 304, a p-doped III-N layer may be formed over the barrier layer in the gate region, where the p-doped III-N layer may contain a concentration profile of an element with one or more peaks at different distances from a surface of the p-doped III-N layer. In some examples, the p-doped III-N layer may be formed using a pulsed epitaxy process using appropriate precursors of the element as previously noted. In some examples, these acts may relate to aspects of stages shown in FIGS. 1A-1F, which may be followed by the formation of device electrodes in a gate first process or a gate last process depending on implementation.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), plasma enhanced CVD (PECVD), or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately or directly over the other component, or that one component is immediately or directly under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B. ” Reference to an element in the singular is not intended to mean “one and only one” unless explicitly so stated, but rather “one or more. ” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A semiconductor device, comprising:
a semiconductor substrate including a source region, a gate region, a drain region, and a drain access region between the gate region and the drain region;
a heterojunction structure over the semiconductor substrate, the heterojunction structure including a buffer layer over the semiconductor substrate and a barrier layer over the buffer layer; and
a p-doped III-N layer over the barrier layer in the gate region, the p-doped III-N layer containing a concentration profile of an element with one or more peaks at different distances from a surface of the p-doped III-N layer.

2. The semiconductor device of claim 1, wherein the element is aluminum, boron, thallium or indium.

3. The semiconductor device of claim 1, wherein the one or more peaks are interspersed within the p-doped III-N layer.

4. The semiconductor device of claim 1, wherein the p-doped III-N layer includes magnesium (Mg) with a concentration of about 1×10¹⁷ atoms/cm³ to 1×10²¹ atoms/cm³.

5. The semiconductor device of claim 1, wherein the one or more peaks are spaced apart by a distance ranging from about 1 nanometer (nm) to about 20 nm.

6. The semiconductor device of claim 1, further comprising an AlGaN cap layer over the p-doped III-N layer.

7. The semiconductor device of claim 1, further comprising a silicon nitride (SiN) cap layer over the p-doped III-N layer.

8. The semiconductor device of claim 1, wherein the p-doped III-N layer is a GaN layer having a thickness of about 20 nm to 200 nm.

9. A semiconductor device, comprising:
a semiconductor substrate including a source region, a gate region, a drain region, and a drain access region between the gate region and the drain region;
a heterojunction structure over the semiconductor substrate, the heterojunction structure including a buffer layer over the semiconductor substrate and a barrier layer over the buffer layer; and
a p-doped III-N layer over the barrier layer in the gate region, the p-doped III-N layer including one or more Al_{X}Ga_{(1-X)}N layers.

10. The semiconductor device of claim 9, wherein the one or more Al_{X}Ga_{(1-X)}N layers are interspersed in the p-doped III-N layer.

11. The semiconductor device of claim 9, wherein the one or more AlXGa(1-X)N layers each have a thickness in a range of about 1 nm to 20 nm.

12. The semiconductor device of claim 9, wherein at least one Al_{X}Ga_{(1-X)}N layer of the one or more Al_{X}Ga_{(1-X)}N layers corresponds to an aluminum nitride (AlN) layer.

13. A method of fabricating a III-N semiconductor device, comprising:
forming a heterojunction structure over a semiconductor substrate including a source region, a gate region, a drain region, and a drain access region between the gate region and the drain region, the heterojunction structure including a buffer layer over the semiconductor substrate and a barrier layer over the buffer layer; and
forming a p-doped III-N layer over the barrier layer in the gate region, the p-doped III-N layer containing a concentration profile of an element with one or more peaks at different distances from a surface of the p-doped III-N layer.

14. The method of claim 13, wherein the p-doped III-N layer is grown using an epitaxial process with pulsed doping of the element.

15. The method of claim 13, wherein the element is aluminum, boron, thallium or indium.

16. The method of claim 13, wherein the one or more peaks are interspersed within the p-doped III-N layer, and wherein the p-doped III-N layer includes magnesium (Mg) with a concentration of about 1×10¹⁷ atoms/cm³ to 1×10²¹ atoms/cm³.

17. The method of claim 13, wherein the one or more peaks are spaced apart by a distance ranging from about 1 nm to about 20 nm.

18. The method of claim 13, further comprising:
forming an AlGaN cap layer over the p-doped III-N layer.

19. The method of claim 13, further comprising:
forming a silicon nitride (SiN) cap layer over the p-doped III-N layer.

20. The method of claim 13, wherein the p-doped III-N layer is a GaN layer having a thickness of about 20 nm to 200 nm.
